(19) United States
(12) Patent Application Publication
(10) Pub. No.: US 2018/0166540 A1
(43) Pub. Date: Jun. 14, 2018

(54) SEMICONDUCTOR DEVICE AND METHOD MANUFACTURING THE SAME

(71) Applicants: Hyundai Motor Company, Seoul (KR); Kia Motors Corporation, Seoul (KR)

(72) Inventor: DAE HWAN CHUN, Gwangmyeong-si (KR)

(73) Assignees: Hyundai Motor Company, Seoul (KR); Kia Motors Corporation, Seoul (KR)

(21) Appl. No.: 15/632,125

(22) Filed: Jun. 23, 2017

(30) Foreign Application Priority Data
Dec. 13, 2016 (KR) 10-2016-0169844

(51) Int. Cl. H01L 29/16; H01L 29/78; H01L 29/417; H01L 29/66

(52) U.S. Cl. CPC H01L 29/1608; H01L 29/66068; H01L 29/41766; H01L 29/7839

(57) ABSTRACT

A semiconductor device may include an n− type layer disposed at a first surface of an n+ type silicon carbide substrate; a trench disposed at the n− type layer; a p type region, an n+ type region, and a p+ type region disposed at an upper portion in the n− type layer; a gate insulating layer disposed on the n− type layer, the n+ type region, and the p type region; a gate electrode disposed on the gate insulating layer; an insulating layer disposed on the gate electrode; a source electrode disposed on the insulating layer and in the trench; and a drain electrode disposed at a second surface of the n+ type silicon carbide substrate, wherein the source electrode includes an ohmic junction region and a Schottky junction region.

### CROSS-REFERENCE(S) TO RELATED APPLICATIONS

The present application claims priority to Korean Patent Application No. 10-2016-0169844, filed on Dec. 13, 2016, the entire contents of which are incorporated herein for all purposes by this reference.

### BACKGROUND OF THE INVENTION

### Field of the Invention

The present invention relates to a semiconductor device including a silicon carbide (SiC) and a manufacturing method thereof.

### Description of Related Art

A power semiconductor device requires a low on-resistance or a low saturation voltage to reduce a power loss in a conduction state while allowing a particularly large current to flow. Also, a characteristic that can withstand a reverse direction high voltage of a PN junction applied to both ends of the power semiconductor device at an off state or the moment that a switch is turned off, that is, a high breakdown voltage characteristic, is required.

For modularizing the multiple power semiconductor devices satisfying a basic electrical condition and physical property condition into one package, a number and an electrical specification of the power semiconductor devices in the power semiconductor module may be changed depending on conditions required in a system.

In general, a three-phase power semiconductor module is used to form a Lorentz force for driving a motor. That is, a driving state is determined by controlling a current and a power that are input to the motor through the three-phase power semiconductor module.

A conventional silicon IGBT (Insulated Gate Bipolar Transistor) and a silicon diode are applied in the three-phase power semiconductor module however, there is recently a trend of applying a silicon carbide (SiC) metal oxide semiconductor field effect transistor (MOSFET) and a silicon carbide diode for minimization of a power consumption generated in the three-phase module and increasing switching speed of the module.

When connecting the silicon IGBT or the silicon carbide MOSFET to another diode, a plurality of wiring connections are made, however an existence of a parasitic capacitance and an inductance due to the wiring reduce a switching speed of the module.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various embodiments of the present invention relates to a silicon carbide semiconductor device performing the MOSFET operation and the diode operation.

A semiconductor device according to an exemplary embodiment of the present invention includes an n− type layer disposed at a first surface of an n+ type silicon carbide substrate; a trench disposed at the n− type layer; a p type region, an n+ type region, and a p+ type region disposed at an upper portion in the n− type layer; a gate insulating layer disposed on the n− type layer, the n+ type region, and the p type region; a gate electrode disposed on the gate insulating layer; an insulating layer disposed on the gate electrode; a source electrode disposed on the insulating layer and in the trench; and a drain electrode disposed at a second surface of the n+ type silicon carbide substrate, wherein the source electrode includes an ohmic junction region and a Schottky junction region.

The n+ type region may be disposed at a side surface of the trench.

The p+ type region may extend from the side surface of the trench to a lower surface of the trench.

The p+ type region may be disposed under the n+ type region.

The source electrode may be in contact with the n+ type region at the side surface of the trench.

The source electrode may be in contact with the p+ type region at the side surface of the trench and the lower surface of the trench.

The source electrode may be in contact with the n− type layer at the lower surface of the trench.

The ohmic junction region may be disposed at a contact portion of the source electrode and the n+ type region as well as the contact portion of the source electrode and the p+ type region.

The Schottky junction region may be disposed at the contact portion of the source electrode and the n− type layer.

An ion doping concentration of the p+ type region may be greater than the ion doping concentration of the p type region.

The p type region may be separated from the trench and may be in contact with the n+ type region and the p+ type region.

The semiconductor device according to an exemplary embodiment of the present invention may further include a p− type region having the ion doping concentration that is smaller than the ion doping concentration of the p type region.

The p type region may be separated from the trench and may be in contact with the n+ type region and the p+ type region, and the p− type region may be disposed under the p+ type region.

A semiconductor device according to an exemplary embodiment of the present invention may further include a high concentration p type region having the ion doping concentration that is greater than the ion doping concentration of the p type region and is smaller than the ion doping concentration of the p+ type region.

The p type region may be separated from the trench and may be in contact with the n+ type region, and the high concentration p type region may be disposed under the p+ type region and between the p+ type region and the p type region.

A manufacturing method of a semiconductor device according to an exemplary embodiment of the present invention includes forming an n− type layer at a first surface of an n+ type silicon carbide substrate; forming a p type region in the n− type layer; forming an n+ type region on the p type region and in the n− type layer; forming a gate insulating layer on the n− type layer, the n+ type region, and the p type region, and forming a gate electrode on the gate insulating layer; forming an insulating layer on the gate electrode and the gate insulating layer, and etching the insulating layer, the gate insulating layer and the n− type layer to form a trench; forming a p+ type region under a side surface and a lower surface of the trench; and forming a source electrode on the insulating layer and in the trench, and forming a drain electrode at a second surface of the n+ type silicon carbide substrate, wherein the source electrode includes an ohmic junction region and a Schottky junction region.

According to an exemplary embodiment of the present invention, as the source electrode includes the ohmic junction region and the Schottky junction region, the semiconductor device may execute the MOSFET operation and the diode operation. Accordingly, a wiring connecting a conventional MOSFET device and a conventional diode device may be omitted wherein an area of the device may be reduced.

Also, as one semiconductor device executes the MOSFET operation and the diode operation without the wiring, a switching speed of the semiconductor device may be improved and a loss of a power may be reduced.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a view schematically depicting an example of a cross-sectional of a semiconductor device according to an exemplary embodiment of the present invention.

FIG. 2 is a view depicting a MOSFET operation state of the semiconductor device according to FIG. 1.

FIG. 3 is a view depicting a simulation result of a MOSFET operation state of the semiconductor device according to FIG. 1.

FIG. 4 is a view depicting a diode operation state of the semiconductor device according to FIG. 1.

FIG. 5 is a view depicting a simulation result of a diode operation state of the semiconductor device according to FIG. 1.

FIG. 6, FIG. 7, FIG. 8, FIG. 9, FIG. 10, and FIG. 11 are views schematically depicting an example of a manufacturing method of a semiconductor device according to an exemplary embodiment of the present invention.

FIG. 12 is a view schematically depicting an example of a cross-sectional of a semiconductor device according to another exemplary embodiment of the present invention.

FIG. 13 is a view schematically depicting an example of a cross-sectional of a semiconductor device according to another exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is intended to cover not only the exemplary embodiments, but also various alternatives, modifications, equivalents and other embodiments, which may be included within the spirit and scope of the invention as defined by the appended claims.

In the drawings, the thicknesses of layers and regions are exaggerated for clarity. Also, when a layer is referred to as being “on” another layer or substrate, it may be directly formed on another layer or substrate, or a third layer may be interposed between them.

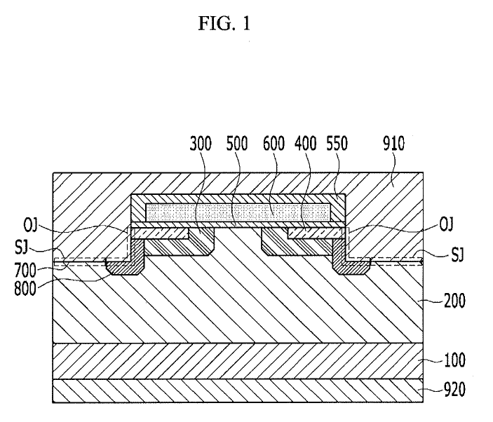

FIG. 1 is a view schematically depicting an example of a cross-sectional of a semiconductor device according to an exemplary embodiment of the present invention.

Referring to FIG. 1, a semiconductor device according to the present exemplary embodiment includes an n+ type silicon carbide substrate 100, an n− type layer 200, a p type region 300, an n+ type region 400, a gate electrode 600, a p+ type region 800, a source electrode 910, and a drain electrode 920.

The n− type layer 200 is disposed at a first surface of the n+ type silicon carbide substrate 100, and a trench 700 is disposed at the n− type layer 200.

The p type region 300, the n+ type region 400, and the p+ type region 800 are disposed at an upper portion in the n− type layer 200. The n+ type region 400 and the p+ type region 800 are in contact with each other and are disposed at a side surface of the trench 700. The n+ type region 400 is disposed on the p+ type region 800. The p+ type region 800 is partially disposed under a lower surface of the trench 700. That is, the p+ type region 800 encloses a corner of the trench 700 at the side surface of the trench 700 and extends to the lower surface. The p type region 300 is separated from the trench 700 and is in contact with the n+ type region 400 and the p+ type region 800. Here, an ion doping concentration of the p+ type region 800 is greater than the ion doping concentration of the p type region 300.

The gate insulating layer 500 is disposed on the n− type layer 200, the p type region 300, and the n+ type region 400, and the gate electrode 600 is disposed on the gate insulating layer 500. The insulating layer 550 is disposed on the gate electrode 600. The insulating layer 550 covers the side surface of the gate electrode 600.

The source electrode 910 is disposed on the insulating layer 550 and in the trench 700, and the drain electrode 920 is disposed at a second surface of the n+ type silicon carbide substrate 100. Here, the second surface of the n+ type silicon carbide substrate 100 indicates a surface opposite to the first surface of the n+ type silicon carbide substrate 100.

As the source electrode 910 is disposed in the trench 700, the source electrode 910 is in contact with the n+ type region 400 disposed at the side surface of the trench 700. Also, the source electrode 910 is in contact with the p+ type region 800 at the side surface and the lower surface of the trench 700. Also, the source electrode 910 is in contact with the n− type layer 200 disposed at the lower surface of the trench 700.

The source electrode 910 includes an ohmic junction region OJ and a Schottky junction region SJ. The ohmic junction region OJ is disposed at a contact portion of the source electrode 910 and the n+ type region 400 as well as the contact portion of the source electrode 910 and the p+ type region 800, and the Schottky junction region SJ is disposed at the contact portion of the source electrode 910 and the n− type layer 200.

As the source electrode 910 includes the ohmic junction region OJ and the Schottky junction region SJ, the MOSFET (metal oxide semiconductor field effect transistor) operation and the diode operation are separately realized depending on the voltage application state in the semiconductor device according to an exemplary embodiment of the present invention. That is, the semiconductor device according to an exemplary embodiment of the present invention includes a MOSFET region and a diode region.

As above-described, as the semiconductor device according to the present exemplary embodiment includes the MOSFET region and the diode region, a wiring connecting a conventional MOSFET device and a conventional diode device is not required. Accordingly, an area of the device may be reduced.

Also, as one semiconductor device includes the MOSFET region and the diode region without the wiring, a switching speed of the semiconductor device may be improved.

On the other hand, the p type region 300 and the p+ type region 800 that are disposed in the n− type layer 200 are in contact with the n− type layer 200 to form the PN junction. The PN junction shows a curved shape by a shape of the p type region 300 and the p+ type region 800.

In an off state of the semiconductor device, an electric field is concentrated to the curved PN junction part and the Schottky junction region SJ. Accordingly, as a position of the electric field concentration may be varied, the breakdown voltage of the semiconductor device may be increased.

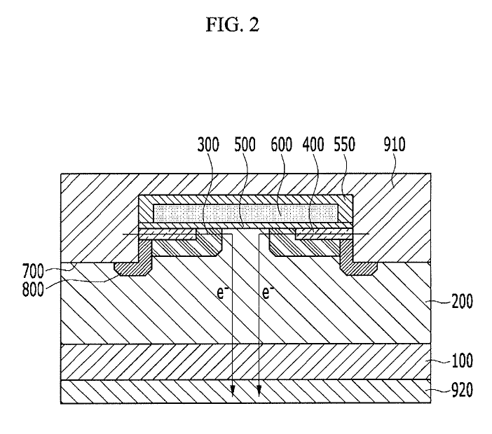

Next, the operation of the semiconductor device according to an exemplary embodiment of the present invention will be described with reference to FIG. 2 to FIG. 5.

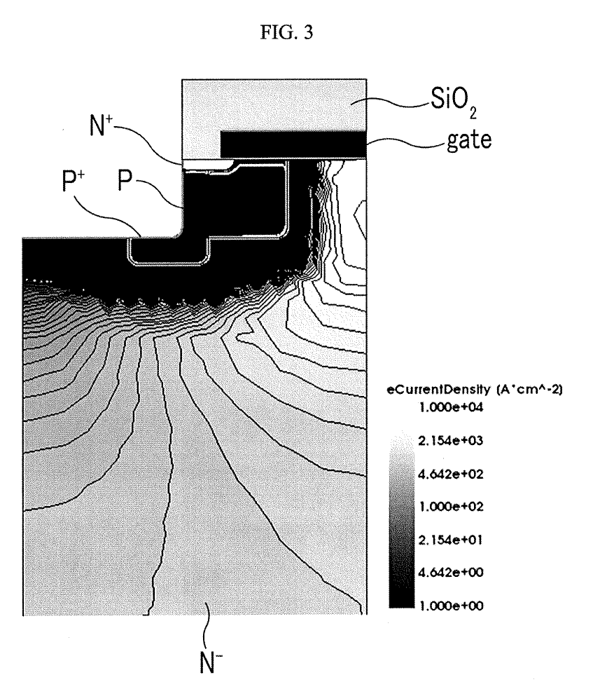

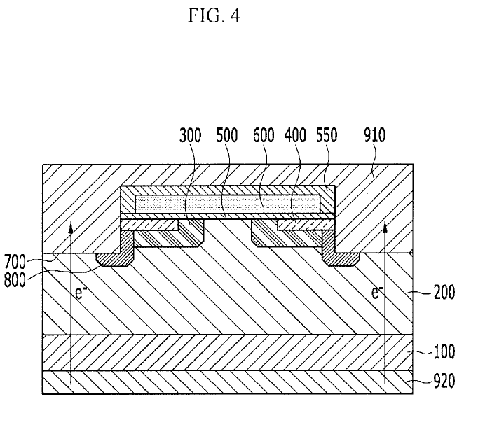

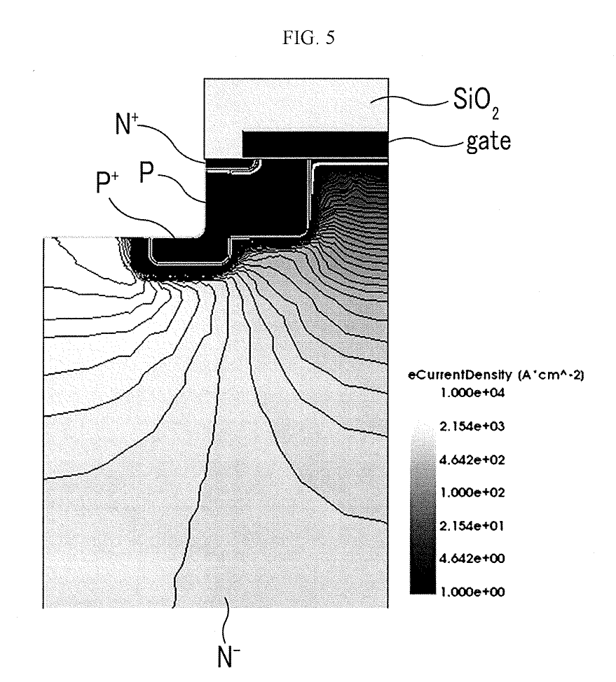

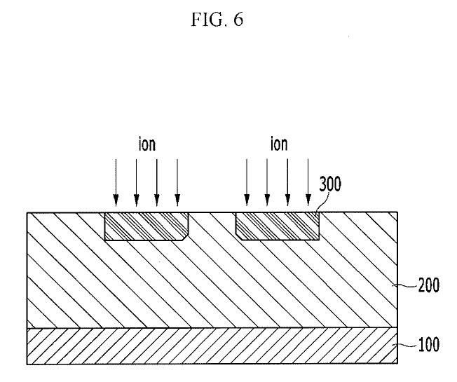

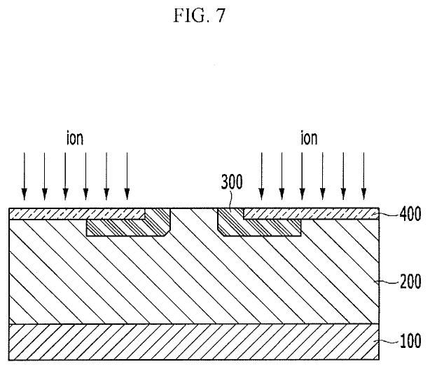

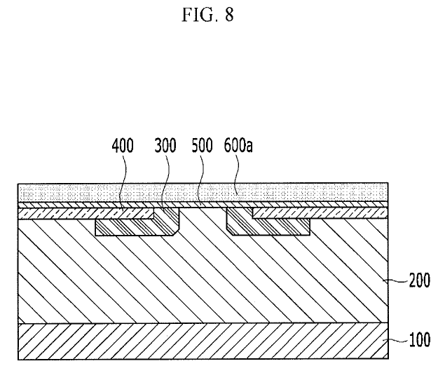

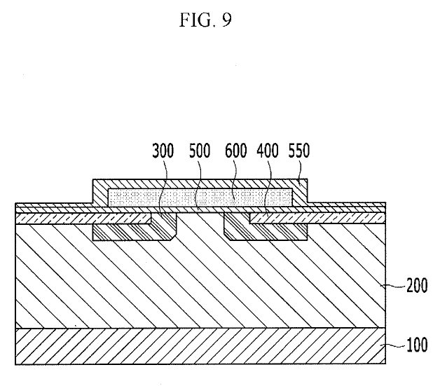

FIG. 2 is a view depicting a MOSFET operation state of the semiconductor device according to FIG. 1. FIG. 3 is a view depicting a simulation result of a MOSFET operation state of the semiconductor device according to FIG. 1. FIG. 4 is a view depicting a diode operation state of the semiconductor device according to FIG. 1. FIG. 5 is a view depicting a simulation result of a diode operation state of the semiconductor device according to FIG. 1.

The MOSFET operation state of the semiconductor device is achieved with a following condition.

V_{GS}≥V_{TH}, V_{DS}>0 V

The diode operation state of the semiconductor device is achieved with a following condition.

V_{GS}<V_{TH}, V_{DS}<0 V

Here, V_{TH} is a threshold voltage of the MOSFET, V_{GS} is (V_{G}−V_{S}), and V_{DS} is (V_{D}−V_{S}). V_{G} is a voltage applied to the gate electrode, V_{D} is a voltage applied to the drain electrode, and V_{S} is a voltage applied to the source electrode.

Referring to FIG. 2, during the MOSFET operation of the semiconductor device, electrons (e−) move from the source electrode 910 to the drain electrode 920. In the present case, the channel is formed in the p type region 300 disposed under the gate electrode 600 wherein a moving path of the electrons (e−) is obtained. That is, the electrons (e−) emitted from the source electrode 910 move to the drain electrode 920 through the p type region 300 and the n− type layer 200 that are disposed under the gate electrode 600.

Referring to FIG. 3, during the MOSFET operation of the semiconductor device, it may be confirmed that the electrons, or current, flows to the n+ type region N+ in which the ohmic junction region is formed through the channel formed at the p type region P disposed under the gate electrode (gate).

Referring to FIG. 4, during the diode operation of the semiconductor device, the electrons (e−) move from the drain electrode 920 to the source electrode 910. The drain electrode 920 has a function of a cathode, and the source electrode 910 has a function of an anode. Here, the electrons (e−) emitted from the drain electrode 920 move to the source electrode 910 through the n− type layer 200.

Referring to FIG. 5, during the diode operation of the semiconductor device, it may be confirmed that the electrons, or current, flows through a part that the Schottky junction region is formed. Accordingly, the current amount during the diode operation of the semiconductor device may be controlled by controlling the area of the Schottky junction region. Here, the current amount during the diode operation of the semiconductor device is proportional to the area of the Schottky junction region.

Next, a characteristic comparison between the semiconductor device according to the present exemplary embodiment and a general diode device and a general MOSFET device will be described with reference to Table 1.

Table 1 shows a simulation result of the semiconductor device according to the present exemplary embodiment, and a general diode device and a general MOSFET device Table

A comparative example 1 is a general Junction Barrier Schottky (JBS) diode device, and a comparative example 2 is a general planar gate MOSFET device.

In Table 1, the semiconductor device according to the present exemplary embodiment is controlled to be the near same as the breakdown voltage of the semiconductor device according to the comparative example 1 and the comparative example 2.

TABLE 1

| | Breakdown | Current | Electric current part | |
|---|---|---|---|---|
| | voltage | density | area (cm²) | |
| | (V) | (A/cm²) | @100 A | |
| Comparative | 950 | 324 | 0.309 | 0.513 |
| Example 1 | | | | |
| Comparative | 923 | 489 | 0.204 | |
| Example 2 | | | | |

| | | | | |
|---|---|---|---|---|
| Exemplary | Diode | 933 | 278 | 0.360 |
| embodiment | operation | | | |
| | MOSFET | | 343 | |
| | operation | | | |

Referring to Table 1, the electric current part area in the current amount of 100 A appears to be as 0.309 cm² in the case of the semiconductor device (the diode) according to the comparative example 1 and appears to be as 0.204 cm² in the case of the semiconductor device (the MOSFET) according to the comparative example 2. A sum of the electric current part areas for the current amount of 100 A appears to be as 0.513 cm² in the semiconductor device according to the comparative example 1 and the comparative example 2. In the case of the semiconductor device according to the present exemplary embodiment, the electric current part area for the current amount 100 A appears to be as 0.360 cm².

That is, as the electric current part area for the current amount 100 A, it may be confirmed that the area of the semiconductor device according to the exemplary embodiment is reduced by approximately 29% for the sum area of the semiconductor device according to the comparative examples 1 and 2.

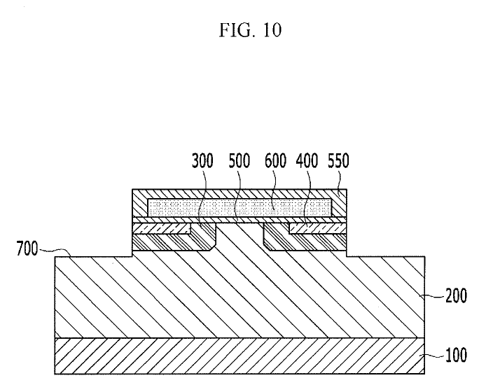

Next, a manufacturing method of the semiconductor device according to an exemplary embodiment of the present invention will be described with reference to FIG. 1 and FIG. 6, FIG. 7, FIG. 8, FIG. 9, FIG. 10, and FIG. 11.

FIG. 6, FIG. 7, FIG. 8, FIG. 9, FIG. 10, and FIG. 11 are views schematically depicting an example of a manufacturing method of a semiconductor device according to an exemplary embodiment of the present invention.

Referring to FIG. 6, an n+ type silicon carbide substrate 100 is prepared, an n− type layer 200 is formed at a first surface of the n+ type silicon carbide substrate 100, and then a p type region 300 is formed at an upper portion in the n− type layer 200. The p type region 300 may be formed by injecting a p type ion including boron (B), aluminum (Al), gallium (Ga), and indium (In) to a portion of the n− type layer 200.

Referring to FIG. 7, an n+ type region 400 is formed on a portion of the p type region 300 and in the n− type layer 200. The n+ type region 400 is formed at a portion of the p type region 300 and a portion of the n− type layer 200, and the n+ type region 400 is formed at the p type region 300 by injecting an n type ion including nitrogen (N), phosphorus (P), arsenic (As), and antimony (Sb) etc. Here, an edge portion of the n+ type region 400 is disposed outside the edge portion of the p type region 300. However, it is not limited thereto, and the edge portion of the p type region 300 and the edge portion of the n+ type region 400 may be on the same line.

Referring to FIG. 8, a gate insulating layer 500 and a gate electrode layer 600a are sequentially formed on the n− type layer 200, the p type region 300, and the n+ type region 400.

Referring to FIG. 9, the gate electrode layer 600a is etched to form a gate electrode 600, and then an insulating layer 550 is formed on the gate insulating layer 500 and the gate electrode 600. The insulating layer 550 covers the side surface of the gate electrode 600.

Referring to FIG. 10, the insulating layer 550, the gate insulating layer 500, and the n− type layer 200 are etched to form a trench 700. In the present case, the parts of the n+ type region 400 and the p type region 300 are etched.

Referring to FIG. 11, the p type ion is injected to the parts of the side surface and the lower surface of the trench 700 to form a p+ type region 800. The ion doping concentration of the p+ type region 800 is greater than the ion doping concentration of the p type region 300.

Here, the p type ion is injected by a tilt ion injection method. The tilt ion injection method is an ion injection method wherein an ion injection angle for a horizontal surface is smaller than a right angle.

Referring to FIG. 1, a source electrode 910 is formed on the insulating layer 550 and in the trench 700, and a drain electrode 920 is formed at a second surface of the n+ type silicon carbide substrate 100.

On the other hand, the semiconductor device according to the present exemplary embodiment includes the p type region 300 and the p+ type region 800 that include the p type conductive material, however it is not limited thereto and a region including the p type conductive material may be further included.

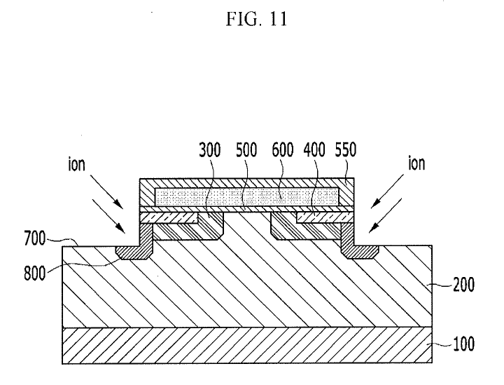

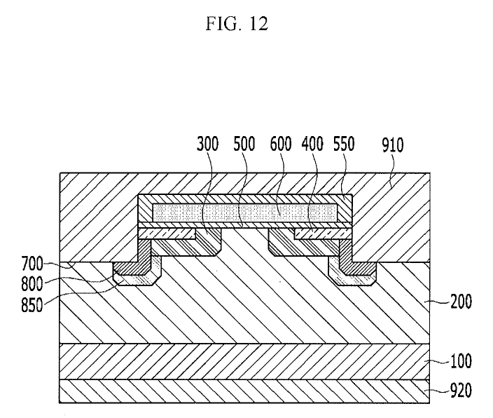

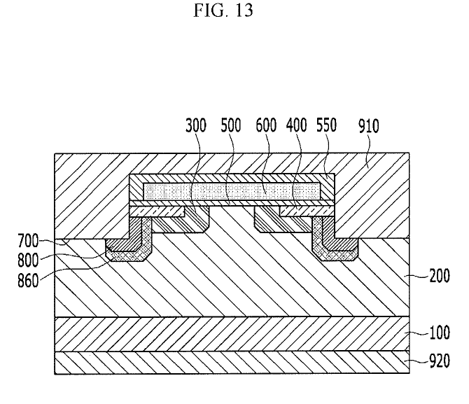

Next, the semiconductor device according to another exemplary embodiment of the present invention will be described with reference to FIG. 12 and FIG. 13.

FIG. 12 is a view schematically depicting an example of a cross-sectional of a semiconductor device according to another exemplary embodiment of the present invention. FIG. 13 is a view schematically depicting an example of across-sectional of a semiconductor device according to another exemplary embodiment of the present invention.

Referring to FIG. 12, the semiconductor device according to the present exemplary embodiment is the same as the semiconductor device according to FIG. 1 except for adding a p− type region 850. Accordingly, the description for the same structure is omitted.

The p− type region 850 is disposed under the p+ type region 800 and the p type region 300. The p− type region 850 is not in contact with the source electrode 910. Here, the ion doping concentration of the p− type region 850 is smaller than the ion doping concentration of the p type region 300. The p− type region 850 may be formed by injecting the p type ion to the side surface and the lower surface of the trench 700 by the tilt ion injection method.

Referring to FIG. 13, the semiconductor device according to the present exemplary embodiment is the same as the semiconductor device according to FIG. 1 except for adding a high concentration p type region 860. Accordingly, the description for the same structure is omitted.

The high concentration p type region 860 is disposed under the p+ type region 800 and between the p+ type region 800 and the p type region 300. The high concentration p type region 860 is not in contact with the source electrode 910. Here, the ion doping concentration of the high concentration p type region 860 is greater than the ion doping concentration of the p type region 300 and is smaller than the ion doping concentration of the p+ type region 800. The high concentration p type region 860 may be formed by injecting the p type ion to the side surface and the lower surface of the trench 700 by the tilt ion injection method.

As above-described, by adding the p− type region 850 or the high concentration p type region 860 to the semiconductor device including the p type region 300 and the p+ type region 800, the breakdown voltage of the semiconductor device may be optimized.

For convenience in explanation and accurate definition in the appended claims, the terms “upper”, “lower”, “internal”, “outer”, “up”, “down”, “upwards”, “downwards”, “front”, “rear”, “back”, “inside”, “outside”, “inwardly”, “outwardly”, “internal”, “external”, “forwards”, and “backwards” are used to describe features of the exemplary embodiments with reference to the positions of such features as displayed in the figures.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described to explain certain principles of the invention and their practical application, to enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A semiconductor device comprising:
an n− type layer disposed at a first surface of an n+ type silicon carbide substrate;
a trench disposed at the n− type layer;
a p type region, an n+ type region, and a p+ type region disposed at an upper portion in the n− type layer;
a gate insulating layer disposed on the n− type layer, the n+ type region, and the p type region;
a gate electrode disposed on the gate insulating layer;
an insulating layer disposed on the gate electrode;
a source electrode disposed on the insulating layer and in the trench; and
a drain electrode disposed at a second surface of the n+ type silicon carbide substrate,
wherein the source electrode includes an ohmic junction region and a Schottky junction region.

2. The semiconductor device of claim 1, wherein
the n+ type region is disposed at a side surface of the trench.

3. The semiconductor device of claim 2, wherein
the p+ type region extends from the side surface of the trench to a lower surface of the trench.

4. The semiconductor device of claim 3, wherein
the p+ type region is disposed under the n+ type region.

5. The semiconductor device of claim 4, wherein
the source electrode is in contact with the n+ type region at the side surface of the trench.

6. The semiconductor device of claim 5, wherein
the source electrode is in contact with the p+ type region at the side surface of the trench and the lower surface of the trench.

7. The semiconductor device of claim 6, wherein
the source electrode is in contact with the n− type layer at the lower surface of the trench.

8. The semiconductor device of claim 7, wherein
the ohmic junction region is disposed at a contact portion of the source electrode and the n+ type region and a contact portion of the source electrode and the p+ type region.

9. The semiconductor device of claim 8, wherein
the Schottky junction region is disposed at a contact portion of the source electrode and the n− type layer.

10. The semiconductor device of claim 9, wherein
an ion doping concentration of the p+ type region is greater than a ion doping concentration of the p type region.

11. The semiconductor device of claim 10, wherein
the p type region is separated from the trench and is in contact with the n+ type region and the p+ type region.

12. The semiconductor device of claim 10, further including:
a p− type region having the ion doping concentration that is smaller than the ion doping concentration of the p type region.

13. The semiconductor device of claim 12, wherein
the p type region is separated from the trench and is in contact with the n+ type region and the p+ type region, and
the p− type region is disposed under the p+ type region.

14. The semiconductor device of claim 10, further including:
a high concentration p type region having the ion doping concentration that is greater than the ion doping concentration of the p type region and is smaller than the ion doping concentration of the p+ type region.

15. The semiconductor device of claim 14, wherein
the p type region is separated from the trench and is in contact with the n+ type region, and
the high concentration p type region is disposed under the p+ type region and between the p+ type region and the p type region.

16. A method for manufacturing a semiconductor device comprising:
forming an n− type layer at a first surface of an n+ type silicon carbide substrate;
forming a p type region in the n− type layer;
forming an n+ type region on the p type region and in the n− type layer;
forming a gate insulating layer on the n− type layer, the n+ type region, and the p type region, and forming a gate electrode on the gate insulating layer;
forming an insulating layer on the gate electrode and the gate insulating layer, and etching the insulating layer, the gate insulating layer, and the n− type layer to form a trench;
forming a p+ type region under a side surface and a lower surface of the trench; and
forming a source electrode on the insulating layer and in the trench, and forming a drain electrode at a second surface of the n+ type silicon carbide substrate,
wherein the source electrode includes an ohmic junction region and a Schottky junction region.

17. The method of claim 16, wherein
the source electrode is in contact with the n+ type region at the side surface of the trench.

18. The method of claim 17, wherein
the source electrode is in contact with the p+ type region at the side surface of the trench and the lower surface of the trench.

19. The method of claim 18, wherein
the source electrode is in contact with the n− type layer at the lower surface of the trench.

20. The method of claim 19, wherein
the ohmic junction region is disposed at a contact portion of the source electrode and the n+ type region and a contact portion of the source electrode and the p+ type region, and
the Schottky junction region is disposed at a contact portion of the source electrode and the n− type layer.
